(19) United States
(12) Patent Application Publication
(10) Pub. No.: US 2026/0033203 A1
(43) Pub. Date: Jan. 29, 2026

(54) PIXEL ARRAY STRUCTURE AND DISPLAY PANEL

(71) Applicant: HKC CORPORATION LIMITED, SHENZHEN (CN)

(72) Inventors: Zhi YANG, SHENZHEN (CN); Yangling TANG, SHENZHEN (CN); Zhisheng XIE, SHENZHEN (CN); Qin LIANG, SHENZHEN (CN); Xiufeng ZHOU, SHENZHEN (CN); Lidan YE, SHENZHEN (CN)

(73) Assignee: HKC CORPORATION LIMITED, SHENZHEN (CN)

(21) Appl. No.: 19/276,035

(22) Filed: Jul. 22, 2025

(30) Foreign Application Priority Data
Jul. 29, 2024 (CF) 202411027441.0

(51) Int. Cl. H10K 59/35; H10K 59/00; H10K 59/122

(52) U.S. Cl. CPC H10K 59/353; H10K 59/122; H10K 59/771

(57) ABSTRACT

A pixel array structure and a display panel are provided. The pixel array structure includes a plurality of pixel units, each of the plurality of pixel units being disposed within a virtual square. Each of the plurality of pixel units includes: a first sub-pixel, having a polygon structure and a first outer boundary, where a geometric center of the first sub-pixel coincides with the pixel center; a second sub-pixel, having an annular structure surrounding the first sub-pixel, and having a second outer boundary and a second inner boundary, where the second inner boundary and the first outer boundary are similar polygon structures arranged concentrically and having the same number of sides; and multiple third sub-pixels, sandwiched between an edge of the virtual square and the second outer boundary, where the multiple third sub-pixels are disposed at multiple vertices of the virtual square in one-to-one correspondence.

### CROSS REFERENCE TO RELATED APPLICATIONS

The present disclosure claims priority of Chinese Patent Application No. 202411027441.0, filed on Jul. 29, 2024, the entire contents of which are hereby incorporated by reference in their entireties.

### TECHNICAL FIELD

The present disclosure relates to the field of display technologies, and in particular to a pixel array structure and a display panel.

### BACKGROUND

An organic light emitting diode (OLED) display panel is a new-type current-type semiconductor light-emitting device, which belongs to a self-luminous technology. Compared with a traditional liquid-crystal display panel, the OLED display panel may have advantages of fast response, high contrast, a wide viewing angle, etc.

In the traditional display panel, a pixel layer is formed by a plurality of pixel units arranged in an array. A single pixel unit usually may include three sub-pixels of different colors which are red, green, and blue. By controlling intensity of three-color components of R, G, and B corresponding to the three sub-pixels in a certain pixel unit, a color and a brightness displayed by the pixel can be controlled. There are various pixel-arranging manners for the existing pixel layer. In the conventional diamond arrangement, each sub-pixel may have a rhombus structure, and the sub-pixels are closely arranged. However, under different product designs, when a shape of one of the sub-pixels is changed, for example, the shape of one of the sub-pixels is changed to a polygon structure with more sides than the rhombus structure, the sub-pixels may no longer be closely arranged. There may be unused parts between the sub-pixels, resulting in a decrease in an overall aperture ratio of the display panel.

### SUMMARY OF THE DISCLOSURE

According to a first aspect, a pixel array structure is provided by some embodiments of the present disclosure. The pixel array structure includes a plurality of pixel units, each of the plurality of pixel units being disposed within a virtual square, where each virtual square has a geometric center, a pixel center is defined on the each of the plurality of pixel units, and the pixel center coincides with the geometric center of the virtual square; where each of the plurality of pixel units includes: a first sub-pixel, having a polygon structure, where a geometric center of the first sub-pixel coincides with the pixel center, and the first sub-pixel have a first outer boundary; a second sub-pixel, having an annular structure surrounding the first sub-pixel, where the second sub-pixel has a second outer boundary and a second inner boundary, each of the second inner boundary and the second outer boundary is a polygon structure, the second inner boundary and the first outer boundary are similar polygon structures, and the similar polygon structures are arranged concentrically and have the same number of sides; and a plurality of third sub-pixels, sandwiched between an edge of the virtual square and the second outer boundary, where the plurality of third sub-pixels are disposed at a plurality of vertices of the virtual square in one-to-one correspondence, the third sub-pixel has a third outer boundary and a third inner boundary, and the third outer boundary coincides with the edge of the virtual square.

According to a second aspect, a display panel is provided by some embodiments of the present disclosure. The a display panel includes a driving substrate; a pixel defining layer, disposed at a side of the driving substrate; a conductive isolation structure, arranged on the pixel defining layer and disposed at a side of the pixel defining layer away from the driving substrate; and the pixel array structure according to the above-mentioned embodiment, where the plurality of pixel units are arranged in a matrix; where a pixel accommodating region is defined by the conductive isolation structure and the pixel defining layer, and the plurality of pixel units are disposed in the pixel accommodating region.

### BRIEF DESCRIPTION OF THE DRAWINGS

In order to more clearly describe the technical solutions in the embodiments of the present disclosure, the following will briefly introduce the drawings required in the description of the embodiments. Obviously, the drawings in the following description are only some embodiments of the present disclosure. For those skilled in the art, other drawings may be obtained based on these drawings without creative work.

FIG. 1 is a schematic structural view of a pixel unit of a pixel array structure according to some embodiments of the present disclosure.

FIG. 2 is a schematic structural view of the pixel unit in a plurality of cases where the number of conducting gaps in the pixel unit shown FIG. 1 is one.

FIG. 3 is a schematic structural view of the pixel unit in a plurality of cases where the number of conducting gaps in the pixel unit shown FIG. 1 is two.

FIG. 4 is a schematic structural view of the pixel unit in a plurality of cases where the number of conducting gaps in the pixel unit shown FIG. 1 is four.

FIG. 5 is a schematic structural view of a plurality of structures of the pixel units shown in FIGS. 2 to 4 and arranged in a matrix.

FIG. 6 is a schematic structural view of a display panel according to some embodiments of the present disclosure.

FIG. 7 is an enlarged view of the display panel shown in FIG. 6 within a virtual square.

FIG. 8 is a cross-sectional view of the display panel in FIG. 7 at any sub-pixel.

FIG. 9 is a schematic structural view of the single isolation unit shown in FIG. 7.

FIG. 10 is a schematic structural view of the pixel unit in a plurality of cases where the number of third isolation portions in the isolation unit shown in FIG. 9 is one.

FIG. 11 is a schematic structural view of the pixel unit in a plurality of cases where the number of third isolation portions in the isolation unit shown in FIG. 9 is two.

FIG. 12 is a schematic structural view of the pixel unit in a plurality of cases where the number of third isolation portions in the isolation unit shown in FIG. 9 is four.

FIG. 13 is a schematic structural view of a plurality of structures of the display panel according to some embodiments of the present disclosure.

### DETAILED DESCRIPTION

The following will be a clear and complete description of the technical solutions in the embodiments of the present disclosure in conjunction with the accompanying drawings in the embodiments of the present disclosure. Obviously, the described embodiments are only a part of the embodiments of the present disclosure, and not all of them. Based on the embodiments in the present disclosure, all other embodiments obtained by those skilled in the art without making creative labor fall within the scope of the present disclosure.

“Embodiment” herein means that a particular feature, structure, or characteristic described with reference to embodiments may be included in at least one embodiment of the present disclosure. The term appearing in various places in the specification are not necessarily as shown in the same embodiment, and are not exclusive or alternative embodiments that are mutually exclusive with other embodiments. Those skilled in the art will understand explicitly and implicitly that the embodiments described herein may be combined with other embodiments.

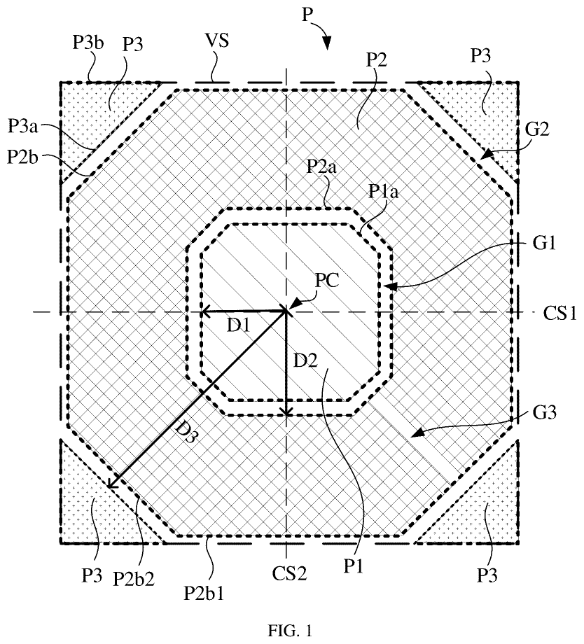

A pixel array structure may be provided by some embodiments of the present disclosure. The pixel array structure may include a plurality of pixel units. As shown in FIG. 1, FIG. 1 is a schematic structural view of a pixel unit of the pixel array structure according to some embodiments of the present disclosure. Each pixel unit P is disposed within a virtual square VS. Each virtual square may have a geometric center. It can be understood that the geometric center of the virtual square VS may be an intersection of two diagonals of the virtual square VS. A pixel center PC may be defined on the each pixel unit P, and the pixel center PC may coincide with the geometric center of the virtual square VS.

The each pixel unit P may include a first sub-pixel P1, a second sub-pixel P2, and a plurality of third sub-pixels P3. The first sub-pixel P1 may have a polygon structure, and a geometric center of the first sub-pixel P1 may coincide with the pixel center PC. The first sub-pixel P1 may have a first outer boundary Pla. The second sub-pixel P2 may be an annular structure surrounding the first sub-pixel P1 and may have a second inner boundary P2a and a second outer boundary P2b. Each of the second inner boundary P2a and the second outer boundary P2b is a polygon structure. The second inner boundary P2a and the first outer boundary Pla may be similar polygon structures and the similar polygon structures may be arranged concentrically and have the same number of sides. The plurality of third sub-pixels P3 may be sandwiched between an edge of the virtual square VS and the second outer boundary P2b, and the plurality of third sub-pixels P3 may be disposed at a plurality of vertices of the virtual square VS in one-to-one correspondence. The third sub-pixel P3 may have a third inner boundary P3a and a third outer boundary P3b, and the third outer boundary P3b may coincide with the edge of the virtual square VS.

A case that the second inner boundary P2a and the first outer boundary Pla may be similar polygon structures and the similar polygon structures may be arranged concentrically and have the same number of sides may be referred to the following meaning. That is, an angel corresponding to a polygon of the second inner boundary P2a may be equal to an angel corresponding to a polygon of the first outer boundary Pla, and a side corresponding to the polygon of the second inner boundary P2a may be proportional to a side corresponding to the polygon of the first outer boundary Pla, such that the similar polygons may be formed. In addition, a spacing between each side of the second inner boundary P2a and a corresponding one of sides of the first outer boundary Pla may be the same.

A ratio of an area of the second sub-pixel to an area of the first sub-pixel may be (2-4): 1, i.e., 2:1-4:1. In some embodiments, the ratio of the area of the second sub-pixel to the area of the first sub-pixel may be 2:1, 3:1, or 4:1.

A shortest distance from the first outer boundary Pla to the pixel center PC may be defined as D1, a shortest distance from the second inner boundary P2a to the pixel center PC may be defined as D2, and a shortest distance from the third inner boundary P3a to the pixel center PC may be defined as D3, where D3>D2>D1. The shortest distance from the first outer boundary Pla to the pixel center PC may be a shortest distance from the pixel boundary of the first sub-pixel P1 to the pixel center PC. The shortest distance from the second inner boundary P2a to the pixel center PC may be a shortest distance from the pixel boundary of the second sub-pixel P2 to the pixel center PC. The shortest distance from the third inner boundary P3a to the pixel center PC may be a straight-line distance from the pixel boundary of the third sub-pixel P3 to the pixel center PC. Therefore, the formula of D3>D2>D1 may be referred to the following meaning. That is, a straight-line distance from the pixel boundary of the first sub-pixel P1 to the pixel center PC may be greater than a straight-line distance from the pixel boundary of the second sub-pixel P2 to the pixel center PC, and the straight-line distance from the pixel boundary of the second sub-pixel P2 to the pixel center PC may be greater than the straight-line distance from the pixel boundary of the third sub-pixel P3 to the pixel center PC.

The above-mentioned shortest distance may be referred to the following meaning. That is, the shortest distance from the first outer boundary Pla to the pixel center PC may be a minimum value of perpendicular distances from each side of the first outer boundary Pla to the pixel center PC. The shortest distance from the second inner boundary P2a to the pixel center PC may be a minimum value of perpendicular distances from each side of the second inner boundary P2a to the pixel center PC. The shortest distance from the third inner boundary P3a to the pixel center PC may be a minimum value of the straight-line distances from each point at the third inner boundary P3a to the pixel center PC.

In the pixel array structure provided in some embodiments of the present disclosure, the each pixel unit P may include the first sub-pixel P1, the second sub-pixel P2, and the plurality of third sub-pixels P3. The second sub-pixel P2 may be an annular structure surrounding the first sub-pixel P1. The second inner boundary P2a and the first outer boundary Pla may be similar polygon structures and the similar polygon structures may be arranged concentrically and have the same number of sides. The plurality of third sub-pixels P3 may be sandwiched between the edge of the virtual square VS and the second outer boundary P2b, and the plurality of third sub-pixels P3 may be disposed at the plurality of vertices of the virtual square VS. Therefore, the new pixel array structure may be formed. In addition, since the second sub-pixel P2 may be an annular structure surrounding the first sub-pixel P1, and the space between an outside of the second sub-pixel P2 and the edge of the virtual square VS may be filled by a corresponding one of the plurality of third sub-pixels P3, such that an area of the unused space may be reduced. In this way, it may be conducive to improving the arrangement density of the sub-pixels and enhancing the space utilization rate, thereby increasing the pixel aperture ratio. In addition, in the pixel unit P provided in some embodiments of the present disclosure, without changing a structure of each of the first sub-pixel P1, the second sub-pixel P2, and the third sub-pixel P3, an area ratio among the sub-pixels may be adjusted by changing a distance between the second inner boundary P2a and the second outer boundary P2b of the second sub-pixel P2, such that it may be more convenient to adjust the area ratio among the sub-pixels.

In some embodiments, the second outer boundary P2b and the first outer boundary Pla may also be similar polygon structures, and the similar polygon structures may be arranged concentrically and have the same number of sides. A case that the second outer boundary P2b and the first outer boundary Pla may also be may be similar polygon structures and the similar polygon structures may be arranged concentrically and have the same number of sides may be referred to the following meaning. That is, an angel corresponding to a polygon of the second outer boundary P2b may be equal to an angel corresponding to a polygon of the first outer boundary Pla, and a side corresponding to the polygon of the second outer boundary P2b may be proportional to a side corresponding to the polygon of the first outer boundary Pla, such that the similar polygons may be formed. In addition, a spacing between each side of the second outer boundary P2b and a corresponding one of sides of the first outer boundary Pla may be the same. Since each of the second inner boundary P2a and the second outer boundary P2b and the first outer boundary Pla may be the similar polygon structures and the similar polygon structures may be arranged concentrically and have the same number of sides, the symmetry of the pixel unit P may be improved.

In some embodiments, corresponding to a shape of the virtual square VS, the number of sides of the second outer boundary P2b may be at least twice that of four. In some embodiments, the second outer boundary P2b may be an octagon, a dodecagon, a hexadecagon, etc. As shown in FIG. 1, a case where the number of sides of the second outer boundary P2b is eight is illustrated. The number of sides of each of the first outer boundary Pla and the second inner boundary P2a may also be eight.

In the embodiments, the second outer boundary P2b may include four parallel boundary segments P2b1 and an inclined boundary segment P2b2. Each of the four parallel boundary segments P2b1 may be parallel to a corresponding one of four sides of the virtual square VS. The inclined boundary segment P2b2 may be connected to adjacent two of the four parallel boundary segments P2b1. The inclined boundary segment P2b2 may be an inclined side. Alternatively, the inclined boundary segment P2b2 may be formed by at least two inclined sides connected in sequence. When the number of sides of the second outer boundary P2b is eight (as shown in FIG. 1), the inclined boundary segment P2b2 is one inclined side. When the number of sides of the second outer boundary P2b is twelve or more, the inclined boundary segment P2b2 is formed by the at least two inclined sides connected in sequence, and each of the at least two inclined sides may be inclined relative to an edge of the virtual square VS. The third sub-pixel P3 may be sandwiched between the inclined boundary segment P2b2 and the edge of the virtual square VS. Since the second sub-pixel P2 may have such a shape, the third sub-pixel P3 may be an axisymmetric structure that is symmetric about a diagonal of the virtual square VS. In some embodiments, when the each pixel unit P is arranged in a matrix, a polygon structure may be formed by four third sub-pixels P3 disposed at an intersection of any four pixel units P arranged in a matrix. Therefore, an overall symmetry of the pixel array structure may be improved, and a uniformity of the display effect of each sub-pixel may be improved.

In the embodiments, each of the four parallel boundary segments P2b1 may have an equal side length. A side length of the inclined boundary segment P2b2 may be equal to or not equal to the side length of the each of the four parallel boundary segments P2b1. When the side length of the inclined boundary segment P2b2 is equal to the side length of the each of the four parallel boundary segments P2b1, and each interior angle of the second outer boundary P2b is equal, a regular octagon may be formed by the second outer boundary P2b. Correspondingly, the first outer boundary Pla and the second inner boundary P2a may be also regular octagons. In this case, the symmetry of the pixel unit P may be improved.

Of course, the number of sides of the second outer boundary P2b in some embodiment of the present disclosure is not limited to a multiple of four, which may also be five, six, seven, nine, ten, fourteen, etc. Compared with other values, the symmetry of the pixel array structure may be better when the number of sides of the second outer boundary P2b is a multiple of four.

Further as shown in FIG. 1, the pixel unit P may be defined with a first pixel central axis CS1 and a second pixel central axis CS2. The first pixel central axis CS1 may be defined along a row direction of the pixel units P arranged in a matrix, and the second pixel central axis CS2 be defined along a column direction of the pixel units P arranged in a matrix.

Each of the first outer boundary Pla, the second inner boundary P2a, and the second outer boundary P2b may be symmetric along the first pixel central axis CS1. Each of the first outer boundary Pla, the second inner boundary P2a, and the second outer boundary P2b may be symmetric along the second pixel central axis CS2. Therefore, the symmetry of the pixel unit P may be improved. In other embodiments, the first outer boundary Pla, the second inner boundary P2a, and the second outer boundary P2b may not be symmetric along the first pixel central axis CS1 and/or the second pixel central axis CS2. The first sub-pixel P1. The second sub-pixel P2, and the third sub-pixel P3 may be configured to emit light of different colors. In some embodiments, the first sub-pixel P1 may be configured to emit green light (G). The second sub-pixel P2 may be s configured to emit blue light (B). The third sub-pixel P3 may be configured to emit red light (R). According to an RGB light-emitting principle, on an OLED screen, the luminous efficiency of the blue light is lower than that of the red light or that of the green light. Therefore, when the aperture is insufficient, it is necessary to increase the current to enable the blue light to reach the required brightness, which may accelerate the decay rate of a blue sub-pixel and affect the lifespan and color accuracy of the entire screen. In the related art, to solve the problem, an area of the blue sub-pixel is usually larger than that of a green sub-pixel or that of a red sub-pixel. In this way, the current passing through the blue sub-pixel may be reduced and the brightness may also be ensured, such that the screen lifespan may be extended. In a single pixel unit P, a ratio of an area of the blue sub-pixel to an area of the green sub-pixel may usually be (2-4):1. In some embodiments, the ratio of the area of the blue sub-pixel to the area of the green sub-pixel may be 2:1, or 3:1, or 4:1. It should be noted that the ratio value herein is only an exemplary representation of the ratio of the area of the blue sub-pixel to the area of the green sub-pixel, which is not limited to the specific ratio.

A position of the blue light may usually remain unchanged, and a position of the red light and a position of the green light may be interchanged. That is, in some embodiments of the present disclosure, the second sub-pixel P2 may also be configured to emit the blue light, the first sub-pixel P1 may be configured to emit the red light, and the third sub-pixel P3 may be configured to emit the green light. It should be understood that in other embodiments, the three sub-pixels with different colors included in the each pixel unit P may also be sub-pixels of other colors, which is not limited to three primary colors of RGB.

In the single pixel unit P, each of the first sub-pixel P1, the second sub-pixel P2, and the third sub-pixel P3 may include an anode, a self-luminous layer, and a cathode arranged in sequence. Self-luminous layers of the first sub-pixel P1, the second sub-pixel P2, and the third sub-pixel P3 may be configured to emit light of different colors, respectively.

Further as shown in FIG. 1, in the single pixel unit P, an inner-gap ring G1 may be defined between the first sub-pixel P1 and the second sub-pixel P2. An outer-gap ring G2 may be defined between the second sub-pixel P2 and the third sub-pixel P3. A conducting gap G3 may be in communication with the inner-gap ring G1 and the outer-gap ring G2. Since the sub-pixels of different colors are formed by an evaporation deposition process in the related art, the following manners may be applied to limit/define positions of the sub-pixels of different colors. A fine metal mask (FMM) evaporation deposition process may be served as one manner. That is, the inner-gap ring G1, the outer-gap ring G2, and the conducting gap G3 may be formed by blocking evaporation materials by a mask during the evaporation process. A conductive isolation structure arranged on the pixel-defining layer may be served as another manner, to replace the mask. That is, the inner-gap ring G1, the outer-gap ring G2, and the conducting gap G3 may be formed by blocking the evaporation materials by the conductive isolation structure during the evaporation process. A connection structure arranged between each of pixel units P and the conductive isolation structure may be described in detail as follows. Here, it is intended to explain a reason that the inner-gap ring G1, the outer-gap ring G2, and the conducting gap G3 may be formed in the pixel unit P.

When each of the first outer boundary Pla, the second inner boundary P2a, and the second outer boundary P2b in FIG. 1 is the octagon, the third inner boundary P3a may be the inclined side, and the inclined side may be parallel to and spaced from the inclined boundary segment P2b2. A shortest distance between the third inner boundary P3a and the pixel center PC may be a straight-line distance between the mid-point of the third inner boundary P3a and the pixel center PC.

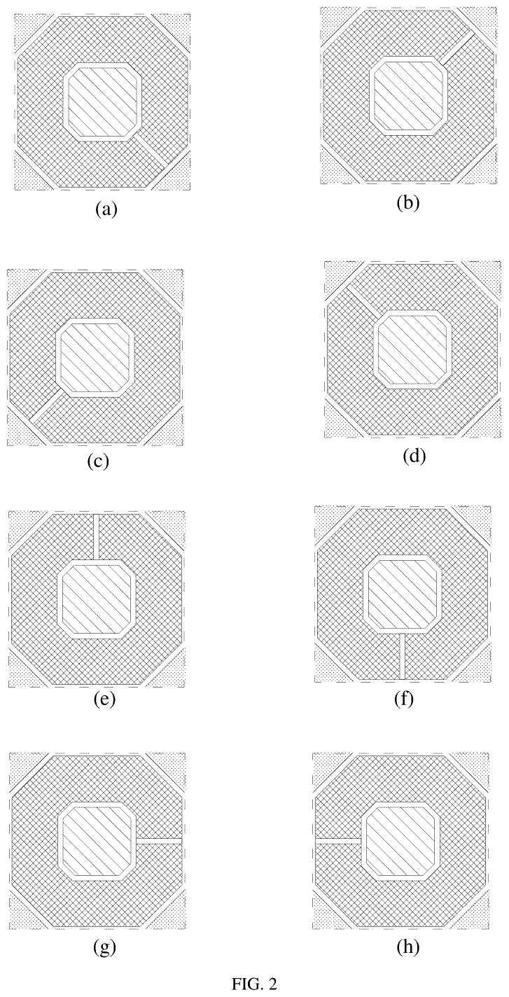

The inner-gap ring G1, the first outer boundary Pla, and the second inner boundary P2a may be similar polygon structures, and the similar polygon structures may be arranged concentrically and have the same number of sides. When the second outer boundary P2b and the first outer boundary Pla may be similar polygon structures, and the similar polygon structures may be arranged concentrically and have the same number of sides, the outer-gap ring G2, the first outer boundary Pla, and the second inner boundary P2a may be also similar polygon structures, and the similar polygon structures may be arranged concentrically and have the same number of sides. Different structures of the conducting gap G3 are illustrated in FIGS. 2-4, and a case where each of the inner-gap ring G1 and the outer-gap ring G2 is the octagon structure may be taken as an example for specific illustration.

A plurality of cases where the number of conducting gaps G3 in the single pixel unit Pis one are illustrated in FIGS. 2(a)-(h). The conducting gap G3 may be connected to a side of the outer-gap ring G2 and a corresponding one of sides of the inner-gap ring G1. The conducting gap G3 may be extended along the first pixel central axis CS1. Alternatively, the conducting gap G3 may be extended along the second pixel central axis CS2. Alternatively, the conducting gap G3 may be arranged at an angle to the first pixel central axis CS1 and the second pixel central axis CS2.

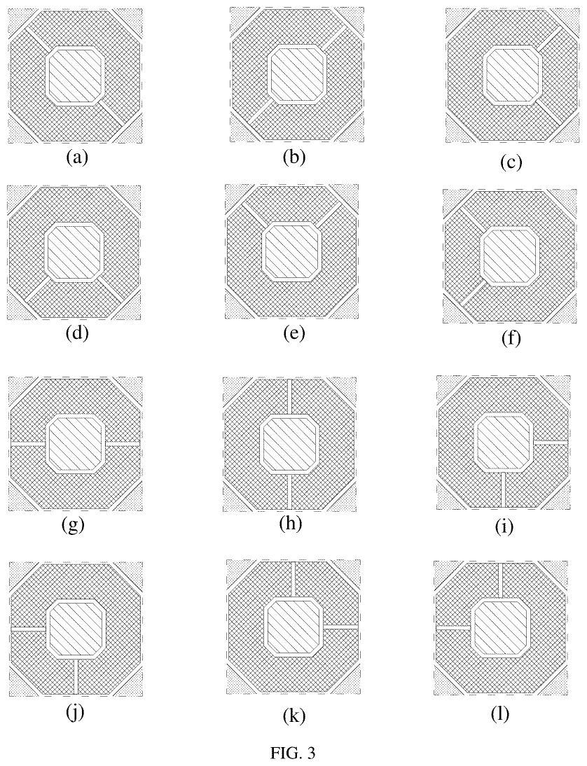

A plurality of cases where the number of conducting gaps G3 in the single pixel unit Pis two are illustrated in FIGS. 3(a)-(l). Two conducting gaps G3 may be respectively connected to different sides of the outer-gap ring G2 and corresponding different sides of the inner-gap ring G1. That is, one of two conducting gaps G3 may be connected to a side of the outer-gap ring G2 and a corresponding one of sides of the inner-gap ring G1. The other one of the two conducting gaps G3 may be connected to another side of the outer-gap ring G2 and another corresponding one of sides of the inner-gap ring G1. The two conducting gaps G3 may be extended along the first pixel central axis CS1 and the second pixel central axis CS2, respectively. Alternatively, each of the two conducting gaps G3 may be arranged at an angle to the first pixel central axis CS1 and the second pixel central axis CS2.

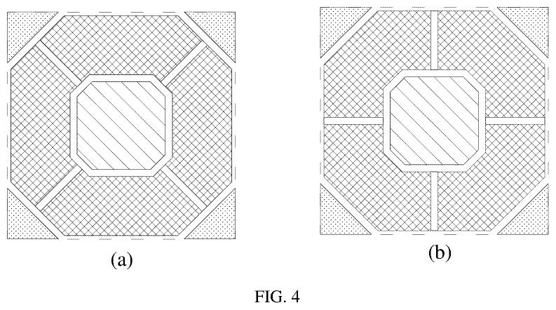

A plurality of cases where the number of conducting gaps G3 in the single pixel unit Pis four are illustrated in FIGS. 4(a)-(b). Four conducting gaps G3 may be respectively connected to different sides of the outer-gap ring G2 and corresponding different sides of the inner-gap ring G1. Two of the four conducting gaps G3 may be extended along the first pixel central axis CS1, and the other two of the four conducting gaps G3 may be extended along the second pixel central axis CS2. Alternatively, each of the four conducting gaps may be arranged at an angle to the first pixel central axis CS1 and the second pixel central axis CS2

In some embodiments, a light-emitting layer of the first sub-pixel P1 is a continuous light-emitting layer. A light-emitting layer of the second sub-pixel P2 is a continuous light-emitting layer or a discontinuous light-emitting layer. A meaning of the continuous light-emitting layer may be referred to a case that a light-emitting surface thereof may be a continuous surface. A meaning of the discontinuous light-emitting layer may be referred to a case that a light-emitting surface thereof may be formed by a plurality of light-emitting surfaces spaced apart from each other.

When the light-emitting layer of the second sub-pixel P2 is the continuous light-emitting layer, the second sub-pixel P2 may be formed by deposition in the same opening area at the same time. When the light-emitting layer of the second sub-pixel P2 is the discontinuous light-emitting layer, the light-emitting layer of the second sub-pixel P2 may be formed into the discontinuous light-emitting layer by the conductive isolation structure described in the following embodiments. When there is one conducting gap G3 in the single pixel unit P, the light-emitting layer of the second sub-pixel P2 may be the continuous light-emitting layer. When the number of the conducting gaps G3 in the single pixel unit P is at least two, the light-emitting layer of the second sub-pixel P2 may be the discontinuous light-emitting layer.

In some embodiments, after the each pixel unit P is arranged in a matrix, the continuous light-emitting layer may be formed by light-emitting layers of two opposite third sub-pixels P3 in any two adjacent pixel units P.

In some embodiments, the continuous light-emitting layer may be formed by light-emitting layers of four third sub-pixels P3 disposed at an intersection of any four pixel units P arranged in a matrix. Therefore, the four third sub-pixels P3 disposed at the intersection of the any four pixel units P arranged in a matrix may be formed by deposition in the same opening area at the same time, such that it may be possible to ensure an opening ratio of the third sub-pixels P3, thereby simplifying the conductive isolation structure. A case where each of the number of sides of the first outer boundary Pla, the number of sides of the second inner boundary P2a, and the number of sides of the second outer boundary P2b is eight is illustrated in FIG. 1. In order to increase the pixel symmetry, the four third sub-pixels P3 in the single pixel unit P may be configured to form an isosceles right triangle structure. After the each pixel unit P is arranged in a matrix, a continuous rhombus-shaped light-emitting layer may be formed by the light-emitting layers of the four third sub-pixels P3 at the intersection of the any four pixel units P arranged in a matrix. That is, a complete rhombus-shaped red sub-pixel may be formed, such that it may be possible to ensure that a shape of the red sub-pixel may remain the same as that of the red sub-pixel in the traditional diamond-arranged structure.

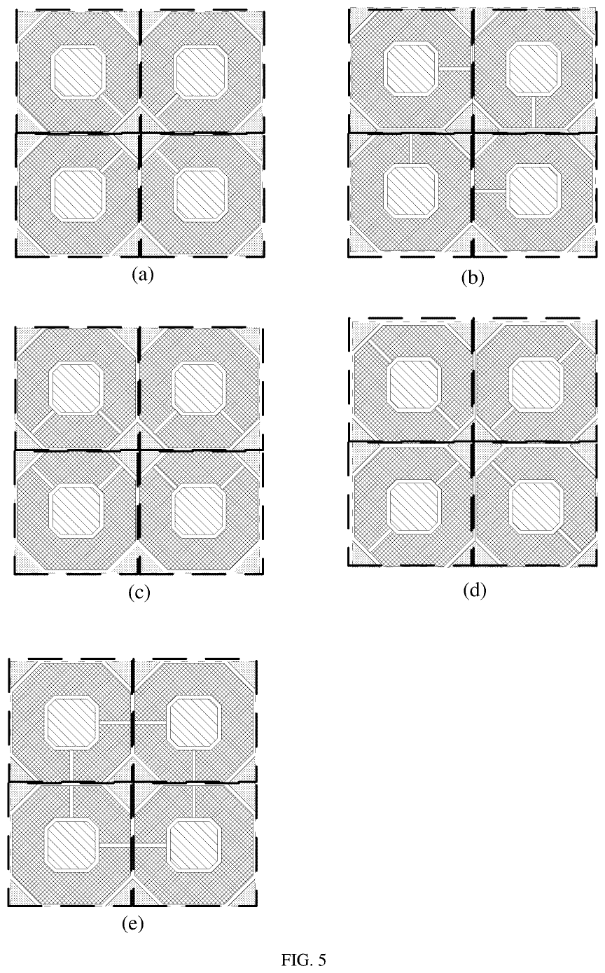

Several representative structures of the pixel units P arranged in a matrix are illustrated in FIGS. 5(a)-(e). Usually, the number of the conducting gaps G3 in the pixel units P arranged in a matrix may be the same. In addition, a symmetric structure may be further formed at an arrangement intersection through a plurality of conducting gaps G3 formed by four pixel units P arranged in a matrix, so as to further increase the symmetry of the pixel arrangement.

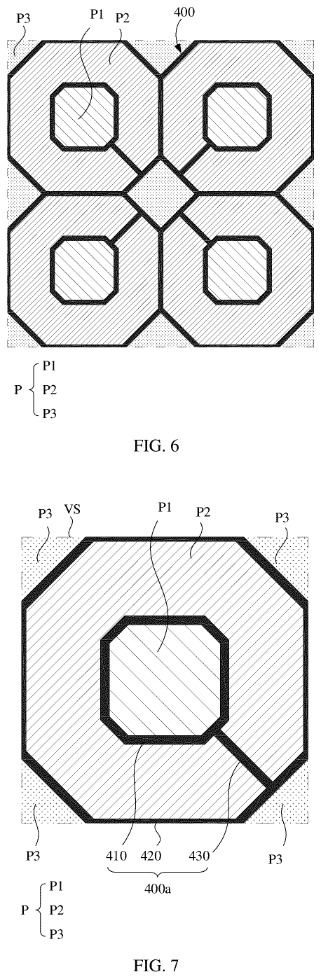

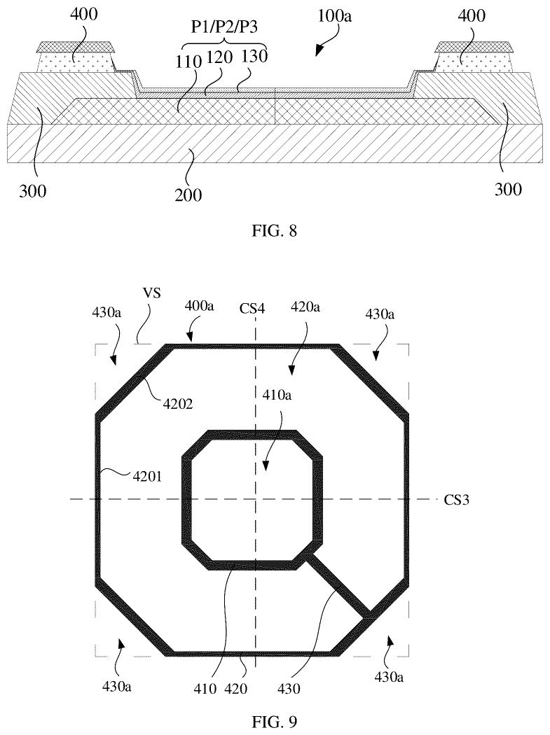

According to a second aspect, a display panel may be provided by some embodiments of the present disclosure. As shown in FIGS. 6-8. FIG. 6 is a schematic structural view of a display panel according to some embodiments of the present disclosure. FIG. 7 is an enlarged view of the display panel shown in FIG. 6 within a virtual square VS. FIG. 8 is a cross-sectional view of the display panel in FIG. 7 at any sub-pixel. The display panel may include a driving substrate 200, a pixel defining layer 300, a conductive isolation structure 400, and a pixel array structure. The pixel array structure may be referred to the above-mentioned embodiments. A plurality of pixel units P may be arranged in a matrix. It should be noted that a matrix arrangement structure of four pixel units P is illustrated in FIG. 6, which is a schematic matrix arrangement. In fact, the number of pixel units P in the display panel is far more than four. Usually, a display panel may include hundreds of thousands of pixel units P or millions of pixel units P.

In the single pixel unit P, each of the first sub-pixel P1, the second sub-pixel P2, and the third sub-pixel P3 may include an anode 110, a self-luminous layer 120, and a cathode 130 arranged in sequence. The self-luminous layers 120 of the first sub-pixel P1, the second sub-pixel P2, and the third sub-pixel P3 may be configured to emit light of different colors, respectively.

The driving substrate 200 may be configured to drive the first sub-pixel P1, the second sub-pixel P2, and the third sub-pixel P3 in the pixel unit P to emit light. The driving substrate 200 may be a Thin Film Transistor (TFT) substrate.

The pixel defining layer 300 may be disposed at a side of the driving substrate 200. The pixel defining layer 300 may be configured to limit positions of the sub-pixels of different colors. In addition, the pixel defining layer 300 may be further configured to isolate the anodes 110 of the sub-pixels of different colors, such that it may be possible to reduce a short-circuit between the anodes 110.

The conductive isolation structure 400 may be disposed on the pixel defining layer 300 and disposed at a side of the pixel defining layer 300 away from the driving substrate 200. The conductive isolation structure 400 may be configured to jointly define/form a pixel accommodating region 100a with the pixel defining layer 300, such that the plurality of pixel units P may be disposed in the pixel accommodating region 100a, and thus the positions of the sub-pixels of different colors may be limited. The conductive isolation structure 400 may be further configured to implement an electrical connection between the cathodes 130 of the sub-pixels.

A traditional red sub-pixel, a traditional green sub-pixel, and a traditional blue sub-pixel may be usually formed by the FMM evaporation deposition process. The display panel provided in some embodiments of the present disclosure may utilize a conductive isolation structure 400 instead of a mask, such that the display panel provided in some embodiments of the present disclosure may be formed by an FMM free (i.e., mask-less) evaporation deposition process. A width of the conductive isolation structure 400 may be smaller than that of the mask. Therefore, a distance/spacing between the sub-pixels of different colors of the display panel may be reduced, thereby increasing the pixel aperture ratio of the display panel.

In some embodiments, the conductive isolation structure 400 may include a plurality of isolation units 400a. The plurality of isolation units 400a may be arranged in a matrix to form the conductive isolation structure 400. Combining with FIG. 7 and FIG. 9, FIG. 9 is a schematic structural view of the single isolation unit 400a shown in FIG. 7. One isolation unit 400a corresponds to one pixel unit P, i.e., the plurality of isolation units 400a and the plurality of pixel units P may be arranged in one-to-one correspondence.

A single isolation unit 400a may be also disposed in the virtual square VS where the corresponding pixel unit P may be disposed. The single isolation unit 400a may include a first isolation portion 410, a second isolation portion 420, and at least one third isolation portion 430. In some embodiments, the first isolation portion 410 may be referred to an inner-ring isolation portion, the second isolation portion 420 may be referred to an outer-ring isolation portion, and the third isolation portion 430 may be referred to a connecting isolation portion. The first isolation portion 410 may be disposed at an inner side of the second isolation portion 420 and may be spaced from the second isolation portion 420. Corresponding to the shape of the first outer boundary Pla and the shape of the second inner boundary P2a, the first isolation portion 410 and the first outer boundary Pla may be similar polygon structures arranged concentrically and have the same number of sides. The second isolation portion 420 and the second outer boundary P2b may be similar polygon structures arranged concentrically and have the same number of sides. The third isolation portion 430 may be disposed between the second isolation portion 420 and the first isolation portion 410. The third isolation portion 430 may be electrically connected to the second isolation portion 420 and the first isolation portion 410. The third isolation portion 430 may be configured to implement an electrical connection between the second isolation portion 420 and the first isolation portion 410.

A first pixel accommodating region 410a may be defined at an inner side of the first isolation portion 410. The first sub-pixel P1 may be correspondingly disposed in the first pixel accommodating region 410a. A second pixel accommodating region may be defined by the first isolation portion 410, the second isolation portion 420, and the at least one third isolation portion 430. The second sub-pixel P2 may be correspondingly disposed in the second pixel accommodating region 420a. A third pixel accommodating region 430a may be defined by the second isolation portion 420 and the edge of the virtual square VS at a top corner of the virtual square VS. The third sub-pixel P3 may be correspondingly disposed in the third pixel accommodating region 430a.

The cathodes 130 of the sub-pixels of different colors mentioned as above may cover the self-luminous layers 120 thereof, and extend to contact the conductive isolation structure 400 to implement an electrical connection between the cathodes 130 of the sub-pixels of different colors. In some embodiments, taking FIGS. 7-8 as examples, for the single pixel unit P, the outer boundary of the cathode 130 of the first sub-pixel P1 may be extended to an inner wall of the first isolation portion 410 to electrically contact the first isolation portion 410. The inner boundary of the third sub-pixel P3 may be extended to an outer wall of the second isolation portion 420 to electrically contact the second isolation portion 420. The inner boundary of the second sub-pixel P2 may be extended to an outer wall of the first isolation portion 410 to electrically contact the first isolation portion 410. The outer boundary of the second sub-pixel P2 may be extended to an inner wall of the second isolation portion 420 to electrically contact the second isolation portion 420. The second sub-pixel P2 may further extend to a side wall of the third isolation portion 430 to electrically contact the third isolation portion 430.

Combining with FIG. 1 and FIG. 7, by arranging the conductive isolation structure 400 in some embodiments of the present disclosure, during the deposition process of an evaporation material, the inner-gap ring G1, the outer-gap ring G2, and the conducting gap G3 in the each pixel unit P may be formed through the isolation effect of the conductive isolation structure 400. Therefore, an actual meaning of the inner-gap ring G1, the outer-gap ring G2, and the conducting gap G3 may be referred to a case that a discontinuous light-emitting surface may be formed by isolating the sub-pixels of different colors through the conductive isolation structure 400, rather than referring to a real-sense gap structure. In some embodiments, for the single pixel unit P, by arranging the first isolation portion 410 of the isolation unit 400a, the inner-gap ring G1 may be formed between the first sub-pixel P1 and the second sub-pixel P2. By arranging the second isolation portion 420, the outer-gap ring G2 may be formed between the second sub-pixel P2 and the third sub-pixel P3. By arranging the third isolation portion 430, the conducting gap G3 may be formed in the second sub-pixel P2.

Corresponding to the aforementioned second outer boundary P2b, the second outer boundary P2b may include the four parallel boundary segments P2b1 respectively parallel to the four sides of the virtual square VS and the inclined boundary segment P2b2 connected to the adjacent two of the four parallel boundary segments P2b1, and the second isolation portion 420 provided in some embodiments of the present disclosure may include four first isolation segments 4201 and an second isolation segments 4202 connected to adjacent two of the four first isolation segments 4201. In some embodiments, the first isolation segments 4201 may be referred to a parallel isolation segment, and the second isolation segments 4202 may be referred to an inclined isolation segment. An outer edge of one of the four first isolation segments 4201 may coincide with a corresponding one of the four sides of the virtual square VS. The second isolation segment 4202 may be an inclined side. Alternatively, the second isolation segment 4202 may be formed by at least two inclined sides connected in sequence. When the number of sides of the second isolation portion 420 may be eight (as shown in FIG. 9), the second isolation segment 4202 may be one inclined side. When the number of the sides of the second isolation portion 420 may be twelve or more, the second isolation segment 4202 may be formed by the at least two inclined sides connected in sequence and each of the at least two inclined sides may be inclined relative to an edge of the virtual square VS. Therefore, in fact, the four first isolation segments 4201 of the second isolation portion 420 may be configured to isolate the second sub-pixels P2 of the two adjacent pixel units P after the pixel units P are arranged. The four second isolation segments 4202 of the second isolation portion 420 may be configured to isolation isolate the second sub-pixel P2 and the third sub-pixel P3 of the two adjacent pixel units P after the pixel units P are arranged.

When the number of third isolation portions 430 of the single isolation unit 400a is one, the light-emitting layer of the second sub-pixel P2 may be the continuous light-emitting layer. When the number of third isolation portions 430 of the single isolation unit 400a may be at least two, the light-emitting layer of the second sub-pixel P2 may be isolated by the at least two third isolation portions 430 to form the discontinuous light-emitting layer.

In some embodiments, the third isolation portion 430 may be approximately perpendicular to a corresponding side of the second isolation portion 420 and a corresponding side of the first isolation portion 410. It should be understood that in other embodiments, the third isolation portion 430 may not be perpendicular to a corresponding side of the second isolation portion 420 or a corresponding side of the first isolation portion 410. The third isolation portion 430 may also be connected to any one side of the second isolation portion 420 and any one side of the first isolation portion 410. The third isolation portion 430 provided in some embodiments of the present disclosure may be configured to electrically connect the second isolation portion 420 and the first isolation portion 410. Therefore, theoretically, as long as the third isolation portion 430 electrically contacts the second isolation portion 420 and the first isolation portion 410, a structure and a shape of the third isolation portion 430 may be not specifically limited.

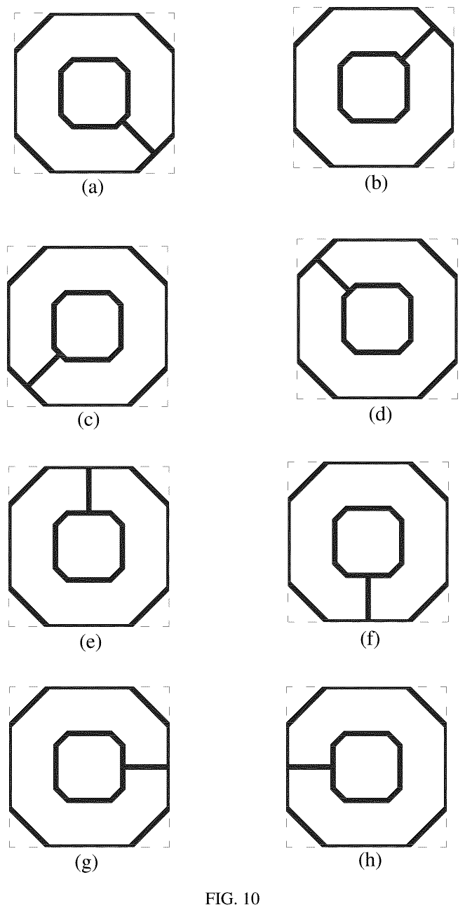

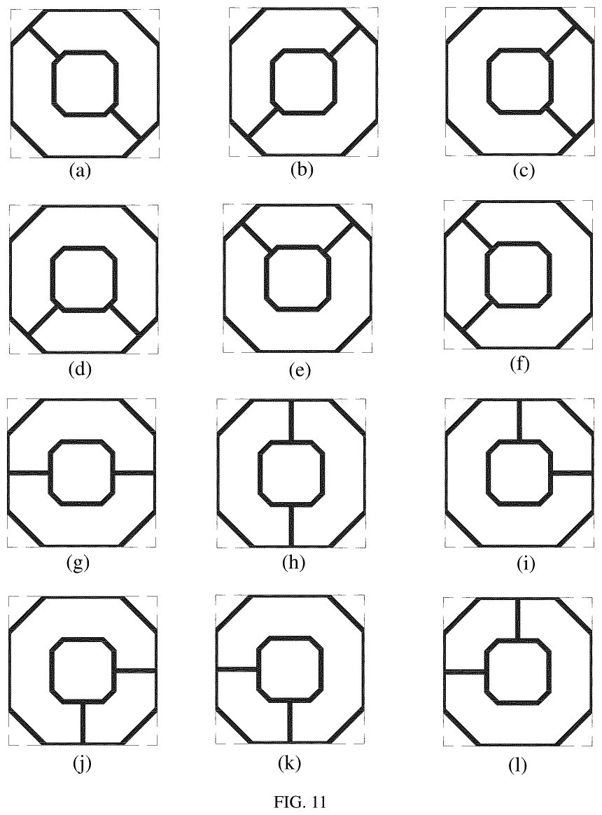

Corresponding to the pixel array structures shown in FIGS. 2-4, different structural forms of the isolation unit 400a are illustrated in FIGS. 10-12. Combing with FIGS. 1, 7, and 9, the isolation unit 400a may be defined with a first isolation central axis CS3 and a second isolation central axis CS4. The first isolation central axis CS3 may be defined along a row direction of the isolation units 400a arranged in a matrix, that is, the first isolation central axis CS3 may be defined along a row direction of the pixel units P arranged in a matrix. The second isolation central axis CS4 may be defined along a column direction of the isolation units 400a arranged in a matrix, that is, the second isolation central axis CS4 may be defined along a column direction of the pixel units P arranged in a matrix. The isolation unit 400a may be an axisymmetric structure along each of the first isolation central axis CS3 and the second isolation central axis CS4. After the each pixel unit P may be formed in the pixel accommodating region 100a, the first isolation central axis CS3 of the single isolation unit 400a may be the first pixel central axis CS1 of a corresponding single pixel unit P. The second isolation central axis CS4 of the single isolation unit 400a may be the second pixel central axis CS2 of the corresponding single pixel unit P. The following takes the structure in which each of the second isolation portion 420 and the first isolation portion 410 of the isolation unit 400a may be the octagons as an example for specific illustration.

A plurality of cases where the number of third isolation portions 430 in the single isolation unit 400a is one are illustrated in FIGS. 10(a)-(h). The third isolation portion 430 may be electrically connected to the corresponding side of the second isolation portion 420 and the corresponding side of the first isolation portion 410. The third isolation portion 430 may be extended along the first isolation central axis CS3. Alternatively, the third isolation portion 430 may be extended along the second isolation central axis CS4. Alternatively, the third isolation portion 430 may be arranged at an angle to each of the first isolation central axis CS3 and the second isolation central axis CS4.

A plurality of cases where the number of third isolation portions 430 in the single isolation unit 400a is two are illustrated in FIGS. 11(a)-(l). Two third isolation portions 430 may be respectively connected to different sides of the second isolation portion 420 and corresponding different sides of the first isolation portion 410. The two third isolation portions 430 may be extended along the first isolation central axis CS3 and the second isolation central axis CS4, respectively. Alternatively, each of the two third isolation portions 430 may be arranged at an angle to each of the first isolation central axis CS3 and the second isolation central axis CS4.

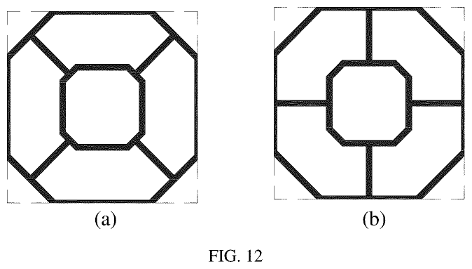

A plurality of cases where the number of third isolation portions 430 in the single isolation unit 400a is four are illustrated in FIGS. 12(a)-(b). Four third isolation portions 430 may be respectively connected to different sides of the second isolation portion 420 and corresponding different sides of the first isolation portion 410. Two of the four third isolation portions 430 may be extended along the first isolation central axis CS3, and the other two the four third isolation portions 430 may be extended along the second isolation central axis CS4. Alternatively, each of the four third isolation portions 430 may be arranged at an angle to each of the first isolation central axis CS3 and the second isolation central axis CS4.

According to a principle of an electrical connection function of the third isolation portion 430, since each of the second isolation portion 420 and the first isolation portion 410 is the polygon structure, a plurality of third isolation portions 430 may be uniformly distributed between the second isolation portion 420 and the first isolation portion 410, such that it may be enable the electrical conduction between the cathodes 130 of the sub-pixels on the entire display panel to be more uniform.

In addition, each of the second isolation portion 420, the first isolation portion 410, and the third isolation portion 430 may have a certain width. Since the plurality of isolation units 400a need to be arranged in a matrix to form the conductive isolation structure 400 of the display panel, relatively contacting parts between adjacent isolation units 400a may share sides after the plurality of isolation units 400a may be arranged in a matrix. In order to simplify a structure and a manufacturing process of the conductive isolation structure 400, each part of the conductive isolation structure 400 may have the same width. That is, the width of each of the first isolation portion 410, the third isolation portion 430, and each second isolation segment 4202 of the second isolation portion 420 may have the same width, and a width of the first isolation segment 4201 may be half of that of the second isolation segment 4201. Therefore, after the plurality of isolation units 400a may be arranged in a matrix, a full width of each of the third isolation portion 430, the second isolation portion 420, and the each second isolation segment 4202 of the first isolation portion 410 may be formed by half widths of the first isolation segments 4201 of two adjacent isolation units 400a, such that it may be possible to enable the each part of the conductive isolation structure 400 to have the same width. It should be understood that in other embodiments, different parts of the conductive isolation structure 400 may also have different widths.

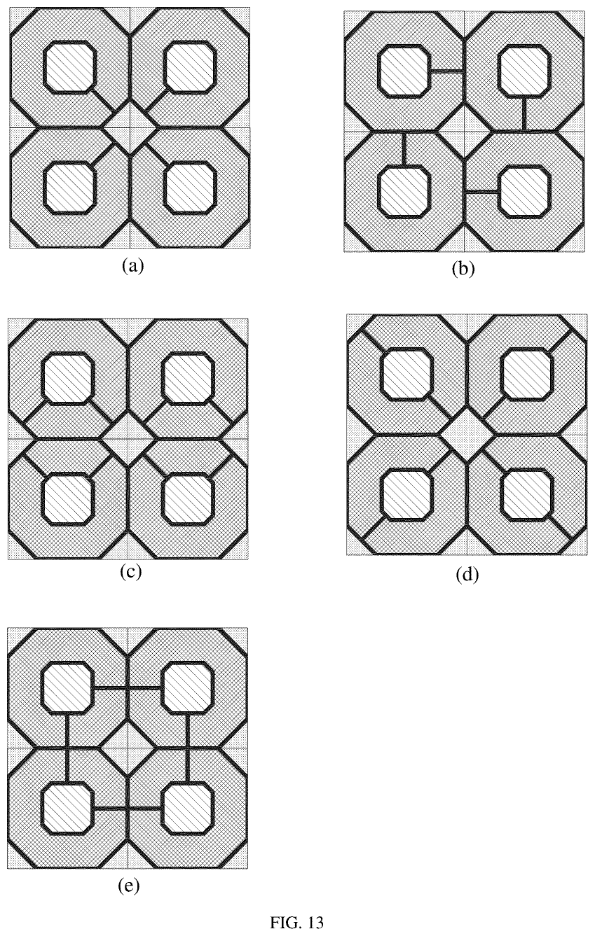

As shown in FIG. 13, FIG. 13 a schematic structural view of a plurality of structures of the display panel according to some embodiments of the present disclosure. Several representative structures of the isolation units 400a and the pixel unit P arranged in a matrix are illustrated in FIGS. 13(a)-(e). Usually, the number of third isolation portions 430 in the isolation units 400a arranged in a matrix may be the same. In addition, a symmetric structure may be further formed at an arrangement intersection through the plurality of third isolation portions 430 formed by the four isolation units 400a arranged in a matrix, so as to further increase the arrangement symmetry of the conductive isolation structure 400, that is, the symmetry of the pixel arrangement may be increased.

Terms “first”, “second” and “third” herein are used for descriptive purposes only and shall not be interpreted as indicating or implying relative importance or implicitly specifying the number of indicated technical features. Therefore, a feature defined by the “first”, “second”, or “third” may explicitly or implicitly include at least one such feature. All directional indications in the present disclosure (such as up, down, left, right, front, rear, . . . ) are used only to explain relative position relationship, movement, and the like, between components at a particular posture (as shown in the drawings). When the posture is changed, the directional indications may change accordingly. In addition, terms “include” and “have” and any variations thereof are intended to cover non-exclusive inclusion. For example, a process, a method, a system, a product, or an apparatus including a series of operations or units is not limited to the listed operations or units, but may further include operations or units that are not listed, or include other operations or units that are inherent to the process, the method, the product, or the apparatus.

The above description shows only embodiments of the present disclosure and does not limit the scope of the present disclosure. Any equivalent structure or equivalent process transformation performed based on the specification and accompanying drawings, applied directly or indirectly in other related fields, shall be equally covered by the scope of the present disclosure.

1. A pixel array structure, comprising:
a plurality of pixel units, each of the plurality of pixel units being disposed within a virtual square, wherein each virtual square has a geometric center, a pixel center is defined on the each of the plurality of pixel units, and the pixel center coincides with the geometric center of the virtual square;
wherein each of the plurality of pixel units comprises:
a first sub-pixel, having a polygon structure, wherein a geometric center of the first sub-pixel coincides with the pixel center, and the first sub-pixel have a first outer boundary;
a second sub-pixel, having an annular structure surrounding the first sub-pixel, wherein the second sub-pixel has a second outer boundary and a second inner boundary, each of the second inner boundary and the second outer boundary is a polygon structure, the second inner boundary and the first outer boundary are similar polygon structures, and the similar polygon structures are arranged concentrically and have the same number of sides; and
a plurality of third sub-pixels, sandwiched between an edge of the virtual square and the second outer boundary, wherein the plurality of third sub-pixels are disposed at a plurality of vertices of the virtual square in one-to-one correspondence, the third sub-pixel has a third outer boundary and a third inner boundary, and the third outer boundary coincides with the edge of the virtual square.

2. The pixel array structure according to claim 1, wherein the second outer boundary and the first outer boundary are similar polygon structures, and the similar polygon structures are arranged concentrically and comprise the same number of sides.

3. The pixel array structure according to claim 1, wherein the first sub-pixel is configured to emit green light, the second sub-pixel is configured to emit blue light, and the third sub-pixel is configured to emit red light.

4. The pixel array structure according to claim 1, wherein a light-emitting layer of the first sub-pixel is a continuous light-emitting layer; and
a light-emitting layer of the second sub-pixel is a continuous light-emitting layer or a discontinuous light-emitting layer.

5. The pixel array structure according to claim 1, wherein a continuous light-emitting layer is formed by light-emitting layers of opposite two of the plurality of third sub-pixels in any adjacent two of the plurality of pixel units.

6. The pixel array structure according to claim 5, wherein a continuous light-emitting layer is formed by light-emitting layers of four of the plurality of third sub-pixels disposed at an intersection of any four of the plurality of pixel units arranged in a matrix.

7. The pixel array structure according to claim 1, wherein a ratio of an area of the second sub-pixel to an area of the first sub-pixel is 2:1-4:1.

8. The pixel array structure according to claim 1, wherein a straight-line distance from a pixel boundary of the first sub-pixel to the pixel center is greater than a straight-line distance from a pixel boundary of the second sub-pixel to the pixel center, and the straight-line distance from the pixel boundary of the second sub-pixel to the pixel center is greater than a straight-line distance from a pixel boundary of the third sub-pixel to the pixel center.

9. The pixel array structure according to claim 1, wherein the second outer boundary comprises four parallel boundary segments and an inclined boundary segment, each of the four parallel boundary segments are parallel to a corresponding one of four sides of the virtual square, and the inclined boundary segment is connected to adjacent two of the four parallel boundary segments; and
the third sub-pixel is sandwiched between the inclined boundary segment and the edge of the virtual square.

10. The pixel array structure according to claim 1, wherein in the single pixel unit, an inner-gap ring is defined between the first sub-pixel and the second sub-pixel, an outer-gap ring is defined between the second sub-pixel and the third sub-pixel, and a conducting gap is in communication with the inner-gap ring and the outer-gap ring.

11. The pixel array structure according to claim 10, wherein the inner-gap ring, the first outer boundary, and the second inner boundary are the similar polygon structures, and the similar polygon structures are arranged concentrically and have the same number of sides;
in a case where the second outer boundary and the first outer boundary are the similar polygon structures, and the similar polygon structures are arranged concentrically and have the same number of sides, the outer-gap ring, the first outer boundary, and the second inner boundary are also similar polygon structures, and the similar polygon structures are arranged concentrically and have the same number of sides.

12. A display panel, comprising:
a driving substrate;
a pixel defining layer, disposed at a side of the driving substrate;
a conductive isolation structure, arranged on the pixel defining layer and disposed at a side of the pixel defining layer away from the driving substrate; and
a pixel array structure, comprising a plurality of pixel units, wherein each of the plurality of pixel units is disposed within a virtual square, each virtual square has a geometric center, a pixel center is defined on the each of the plurality of pixel units, the pixel center coincides with the geometric center of the virtual square, and the plurality of pixel units are arranged in a matrix;
wherein each of the plurality of pixel units comprises:
a first sub-pixel, having a polygon structure, wherein a geometric center of the first sub-pixel coincides with the pixel center, and the first sub-pixel have a first outer boundary;
a second sub-pixel, having an annular structure surrounding the first sub-pixel, wherein the second sub-pixel has a second outer boundary and a second inner boundary, each of the second inner boundary and the second outer boundary is a polygon structure, the second inner boundary and the first outer boundary are similar polygon structures, and the similar polygon structures are arranged concentrically and have the same number of sides; and
a plurality of third sub-pixels, sandwiched between an edge of the virtual square and the second outer boundary, wherein the plurality of third sub-pixels are disposed at a plurality of vertices of the virtual square in one-to-one correspondence, the third sub-pixel has a third outer boundary and a third inner boundary, and the third outer boundary coincides with the edge of the virtual square;
wherein a pixel accommodating region is defined by the conductive isolation structure and the pixel defining layer, and the plurality of pixel units are disposed in the pixel accommodating region.

13. The display panel according to claim 12, wherein the conductive isolation structure comprises a plurality of isolation units arranged in a matrix, and the plurality of isolation units and the plurality of pixel units are arranged in one-to-one correspondence;
a single one of the plurality of isolation units comprises an second isolation portion, an first isolation portion, and at least one third isolation portion, the first isolation portion is disposed at an inner side of the second isolation portion and is spaced from the second isolation portion, the first isolation portion and the first outer boundary are similar polygon structures arranged concentrically and comprise the same number of sides, the second isolation portion and the second outer boundary are similar polygon structures arranged concentrically and comprise the same number of sides, the third isolation portion is disposed between the second isolation portion and the first isolation portion, and the third isolation portion is electrically connected to the second isolation portion and the first isolation portion.

14. The display panel according to claim 13, wherein a first pixel accommodating region is defined at an inner side of the first isolation portion, and the first sub-pixel is correspondingly disposed in the first pixel accommodating region;
a second pixel accommodating region is defined by the first isolation portion, the second isolation portion, and the at least one third isolation portion, and the second sub-pixel is correspondingly disposed in the second pixel accommodating region;
a third pixel accommodating region is defined by the second isolation portion at a top corner of the virtual square and the edge of the virtual square, and the third sub-pixel is correspondingly disposed in the third pixel accommodating region.

15. The display panel according to claim 13, wherein in a case where the number of the at least one third isolation portion of the each of the plurality of isolation units is one, the light-emitting layer of the second sub-pixel is a continuous light-emitting layer, or in a case where the number of the at least one third isolation portion of the single one of the plurality of isolation units is greater than one, the light-emitting layer of the second sub-pixel is isolated by at least two third isolation portions to form the discontinuous light-emitting layer.

16. The display panel according to claim 13, wherein the third isolation portion is perpendicular to a corresponding side of the second isolation portion and a corresponding side of the inner-ring isolation par.

17. The display panel according to claim 13, wherein the isolation unit is defined with a first isolation central axis and a second isolation central axis, the first isolation central axis is defined along a row direction of the isolation units arranged in a matrix, and the second isolation central axis is defined along a column direction of the isolation units arranged in a matrix, the isolation unit is an axisymmetric structure along each of the first isolation central axis and the second isolation central axis.

18. The display panel according to claim 17, wherein in a case where the number of the at least one third isolation portion of the single one of the plurality of isolation units is one, the third isolation portion is electrically connected to a side of the second isolation portion and a corresponding side of the first isolation portion, the third isolation portion is extended along the first isolation central axis or the second isolation central axis, or the third isolation portion is arranged at an angle to each of the first isolation central axis and the second isolation central axis.

19. The display panel according to claim 17, wherein in a case where the number of the at least one third isolation portion of the single one of the plurality of isolation units is two, two third isolation portions are respectively connected to different sides of the second isolation portion and corresponding different sides of the first isolation portion, and the two third isolation portions are extended along the first isolation central axis and the second isolation central axis, respectively, or each of the two third isolation portions are arranged at an angle to each of the first isolation central axis and the second isolation central axis.

20. The display panel according to claim 17, wherein in a case where the number of the at least one third isolation portion of the single one of the plurality of isolation units is four, four third isolation portions are respectively connected to different sides of the second isolation portion and different corresponding sides of the first isolation portion, two of the four third isolation portions are extended along the first isolation central axis, and the other two of the four third isolation portions are extended along the second isolation central axis, or each of the four third isolation portions is arranged at an angle to each of the first isolation central axis and the second isolation central axis.
